(19) United States
(12) Patent Application Publication
(10) Pub. No.: US 2011/0000541 A1
(43) Pub. Date: Jan. 6, 2011

(54) METHOD FOR DEPOSITION A FILM ONTO A SUBSTRATE

(75) Inventors: Uwe Brendel, Salzburg (AT); Herbert Dittrich, Winterbach (DE); Hermann-Josef Schimper, Osann-Monzel (DE); Andreas Stadler, Berchtesgaden (DE); Dan Topa, Salzburg (AT); Angelika Basch, Graz (AT)

Correspondence Address: YOUNG & THOMPSON, 209 Madison Street, Suite 500, Alexandria, VA, 22314, US

(73) Assignee: LAM RESEARCH AG, Villach (AT)

(21) Appl. No.: 12/919,794

(22) PCT Filed: Mar. 2, 2009
(86) PCT No.: PCT/EP2009/052433

§ 371 Date: Aug. 27, 2010

(30) Foreign Application Priority Data
Mar. 14, 2008 (AT) A 416/2008

(51) Int. Cl. H01L 31/0368; C23C 14/06; C23C 14/38

(52) U.S. Cl. 136/258; 204/192.25; 204/192.14; 257/E31.043

(57) ABSTRACT

Disclosed is a method for depositing a film onto a substrate, with a sputter deposition process
wherein the sputter deposition process is a direct current sputter deposition
wherein the film consists of at least 90 wt-% of an inorganic material having semiconductor properties
whereby the film of the inorganic material M2 is directly deposited as crystalline structure, so that at least 50 wt-% of the deposited film has a crystalline structure
wherein the source material (target) used for the sputter deposition consists of at least 80 wt-% of the inorganic material M2.
wherein the inorganic material is selected from a group including binary, ternary, and quaternary compounds including sulphur, selenium, tellurium, indium, and/or germanium.

### TECHNICAL FIELD

The invention relates to a method for depositing a film onto a substrate, with a sputter deposition process and an electrical device manufactured with such a process.

### BACKGROUND ART

It is known in the art that SnS is suitable for use as a solar absorber in optoelectronic devices and photovoltaic applications.

In “Optical properties of thermally evaporated SnS thin films” (M. M. El-Nahass, et. al. Optical Materials 20 (2002) 159-170) it is disclosed that SnS thin films can be prepared by a variety of methods (spray pyrolysis, chemical deposition, or thermal evaporation) with the purpose of manufacturing thin films suitable for use as a solar absorber in optoelectronic devices and photovoltaic applications.

Thermal evaporation of bulk crystalline SnS materials resulted in amorphous films. Crystalline films are generated upon annealing of amorphous SnS films at 200° C.

W. Guang-Pu, et. al. First WCPEC; Dec. 5-9, 1994, Hawaii discloses investigation on SnS film by RF (radio frequency) sputtering for photovoltaic application. RF sputtering (from room temperature up to 350° C. sample temperature) leads to amorphous SnS. After deposition crystalline SnS is formed by annealing at 400° C.

M. Y. Versavel, et. al. Thin Solid Films 515 (2007), 7171-7176 discloses RF (radio frequency) sputtering of Sb₂S₃. The deposited films are amorphous and thus require subsequent annealing at 400° C. in the presence of sulphur vapour.

An object of the invention is to provide an alternative process to prepare a crystalline film of an inorganic material by direct deposition without the necessity of a subsequent treatment step.

### DISCLOSURE OF INVENTION

The invention meets the objects by providing a method for depositing a film onto a substrate, with a sputter deposition process, wherein the sputter deposition process comprises direct current sputter deposition, wherein the film consists of at least 90 wt-% of an inorganic material M2 having semiconductor properties, whereby the film of the inorganic material M2 is directly deposited as crystalline structure, so that at least 50 wt-% of the deposited film has a crystalline structure, wherein the source material (target) used for the sputter deposition consists of at least 80 wt-% of the inorganic material M2. The inorganic material M2 is selected from a group comprising binary, ternary, and quaternary compounds comprising sulphur, selenium, and/or tellurium.

With the direct current sputter deposition inorganic materials which with prior art techniques could not be directly deposited as crystalline structures now could be deposited and crystalline structures were achieved. This leads to the advantage that a subsequent step like annealing at elevated temperatures may be omitted.

The directed sputter deposition process may be overlaid by a RF sputter process and/or a pulsed sputter process (pulsed DC sputtering).

In a preferred embodiment the inorganic material M2 is selected from the group of SnS, Sb₂S₃, Bi₂S₃, and other semiconducting sulphides, selenides, or tellurides such as, CdSe, In₂S₃, In₂Se₃, SnS, SnSe, PbS, PbSe, MoSe₂, GeTe, Bi₂Te₃, or Sb₂Te₃; compounds of Cu, Sb, and S (or Se, Te) (e.g. CuSbS₂, Cu₂SnS₃, CuSbSe₂, Cu₂SnSe₃); compounds of Pb, Sb, and S (or Se, or Te) (PbSnS₃, PbSnSe₃). With this method absorber layers, which are used in thin film photovoltaic, can be directly deposited on a substrate.

Preferably the inorganic material M2 is SnS, Sb₂S₃, Bi₂S₃, SnSe, Sb₂Se₃, Bi₂Se₃, Sb₂Te₃ or a combination thereof (e.g. Snₓ(Sb,Bi)_{y}(S,Se,Te)_{z}). Such materials have not been reported yet to be directly deposited by sputtering methods generating a primarily crystalline structure.

In another embodiment the inorganic material M2 is selected from the group of SnS, Bi₂S₃ or a combination of SnS and Bi₂S₃ (e.g. (SnS)ₓ(Bi₂S₃)_{y}).

Especially for SnS if the crystalline structure is sought to be orthorhombic (like Herzenbergite), the method is advantageous. Previously it was not possible to directly deposit SnS in a highly crystalline form but has to be treated by subsequent annealing.

In another embodiment at least during 90% of the depositing time the temperature T1 of the substrate is kept below 200° C. This brings the advantage that even substrates, which would melt, decompose or deform at elevated temperatures can be coated with such inorganic materials.

If the temperature T1 is kept below 100° C. even polymeric materials like polypropylene, polystyrene or polyethylene can be coated.

With this method the temperature T1 is kept below 60° C. and the coated films are still crystalline.

Advantageously the process parameters (t (time), T (temperature), p (pressure), P (power), U (voltage), . . . ) are set so that the film of the inorganic material M2 is deposited at a deposition rate of at least 60 nm/min (1 nm/s). If the inorganic materials are deposited with DC sputtering the parameters can be set so very high deposition rates can be achieved still generating crystalline layers.

In a preferred embodiment prior to the deposition of the film comprising the inorganic material M2 another layer of an inorganic material M1 has been deposited.

The inorganic material M1 is preferably selected from the group of a metal or a conducting oxide, whereby a backside contacting of an absorbing layer can be generated.

Advantageously the inorganic material M1 has been deposited by sputter deposition. With these deposition methods the layers of M1 and of M2 can be deposited on a substrate without intermediate breakage of vacuum.

In another embodiment the substrate is selected from a group of ceramics, glass, polymer, and plastic. Such materials can be provided as sheets (e.g. foil, woven, non-woven, paper, tissue), fibres, tubes or other modifications.

Another aspect of the invention is the product resulting from one of the above-mentioned methods.

Yet another aspect of the invention is an energy conversion cell such as a Peltier element or a solar cell comprising a product resulting from one of the above-mentioned methods.

Preferably the energy conversion cell (photovoltaic cell or Peltier element) comprises an absorber layer wherein the absorber layer is deposited by one of the above-mentioned methods.

In one embodiment for Peltier element a binary or ternary telluride is used (e.g. Bi₂Te₃)

### BRIEF DESCRIPTION OF DRAWINGS

FIG. 1 shows XRD Data of a SnS crystalline thin film as deposited by a preferred embodiment of the invention on glass substrate.

FIG. 2 shows XRD Data of a SnS crystalline thin film as deposited by a preferred embodiment of the invention on poly propylene (PP) substrate.

FIG. 3 shows absorption of SnS thin film deposited by a preferred embodiment of the invention.

FIG. 4 shows a current voltage characteristic (IN characteristic) of SnS thin film deposited by a preferred embodiment of the invention.

### BEST MODE FOR CARRYING OUT THE INVENTION

Following a preferred embodiment to carry out the invention is described.

Up to three different materials (M1, M2, M3) have been deposited by sputtering. M1 is a metal, M2 is an inorganic photovoltaic absorbing material, and M3 is a transparent conducting material.

The preferred process windows for the relevant parameters are summarized in Table 1. Substrates are therein abbreviated as follows: BSG (boron silicate glass), glass (normal object carrier glass), PP (poly propylene), PE (poly ethylene), Fe (stainless steel plate), Cu (copper plate), Al (Aluminium foil). The selected sputter technique is DC sputtering with or without pulsing. The targets used are formed by hot isostatic pressing (HIP) of the respective powder (e.g. SnS, Bi₂S₃, Sb₂S₃, or a mixture thereof). Sulphur can be used as a pressing aid in a concentration of about 3 mol-%.

TABLE 1

| Parameter | range |
|---|---|
| Target for M2 | SnS, SnS + 3 mol. % S, Bi₂S₃, |
| | Bi₂S₃ + 3 mol. % S, Sb₂S₃ + |
| | 3 mol. % S, SnS + Sb₂S₃, |
| | SnS + Bi₂S₃ + 3 mol. % S |
| substrate | glass, BSG, PP, PE, Fe, Cu, Al |
| M1 | Mo, Ag, Au, ZnO: Al |
| M2 | SnS, Sb₂S₃, Bi₂S₃, Bi₂Te₃ |
| M3 | ZnO, ZnO: Al, InₓSn_{y}O_{z} |
| | (indium tin oxide ITO) |
| sputter gas for M2 | Ar, Ar with 2 vol % H₂ |
| P (W) for M2 | 3-18 |
| p (mbar) for M2 | 0.001-0.050 |
| substrate T for M2 (° C.) | 25-650 |
| pulsing frequency (Hz) for M2 | 0-350 |
| pulsing break (μs) for M2 | 0.5-5 |
| distance target to substrate for M2 (cm) | 4-20 |
| deposition rate for M2 (nm/min) | 10-200 |

Seven different examples with selected values (examples 1-7) are summarized in Table 2. In examples 1, 2, 3, 4, 6, and 7 a single layer was deposited onto the substrate, whereas in example 5a stack of three layers Mo/SnS/ZnO:Al was deposited. Such layers were subsequently deposited in order to form an absorption layer with adjacent contacting layers as used for photovoltaic cells. First Mo is deposited on glass as back contact, than SnS is deposited and finally ZnO:Al is deposited. ZnO:Al is used as transparent contacting oxide (TCO) wherein ZnO is doped with 1-2 wt-% Al, which is sputtered by DC sputter technique from ZnO:Al targets.

All three layers are deposited by DC sputter deposition under basically the same conditions, however in different sputter equipments. The sample was moved from one equipment to the other without intermediately breaking vacuum. Therefore it could be avoided that a freshly deposited layer is exposed to the atmosphere, which is advantageous to the subsequent sputter process.

TABLE 2

| Parameter | Ex. 1 | Ex. 2 | Ex. 3 | Ex. 4 | Ex. 5 | Ex. 6 | Ex. 7 |
|---|---|---|---|---|---|---|---|
| Target for M2 | SnS | SnS | Bi₂S₃ | SnS + Bi₂S₃ + | SnS | Sb₂S₃ | Sb₂S₃ |
| | | | | 3 mol. % S | | | |
| substrate | BSG | PP | glass | glass | glass | glass | glass |
| M1 | — | — | — | — | Mo | — | — |
| M2 | SnS | SnS | Bi₂S₃ | SnₓBi_{y}S_{z} | SnS | Sb₂S₃ | Sb₂S₃ |
| M3 | — | — | — | — | ZnO | — | — |
| sputter gas for M2 | Ar | Ar | Ar | Ar | Ar | Ar | Ar |
| P (W) for M2 | 13 | 13 | 13 | 13 | 13 | 13 | 13 |
| p (mbar) for M2 | 0.003 | 0.005 | 0.005 | 0.005 | 0.005 | 0.005 | 0.005 |
| substrate T | 100 | 25 | 25 | 25 | 25 | 25 | 400 |
| for M2 (° C.) | | | | | | | |
| pulsing frequency | no puls | 25 | no puls | no puls | 25 | 25 | 25 |
| (Hz) for M2 | | | | | | | |
| pulsing break | n.a. | 3 | n.a. | n.a. | 3 | 3 | 3 |
| (μs) for M2 | | | | | | | |
| distance target to | 10 | 10 | 10 | 10 | 10 | 10 | 10 |
| substrate for M2 (cm) | | | | | | | |
| deposition rate for | 100 | 100 | 100 | 100 | 100 | 100 | 100 |
| M2 (nm/min) | | | | | | | |

The listed parameters (t, T, p, P, U, . . . ) in Tables 1 and 2 refer to the sputtering of the inorganic material M2. Sputter parameters for sputter deposition of materials M1 and M3 are not listed as such techniques are well known in the art. Alternatively intermediate layers between the absorber layer (comprising inorganic materials M2) and the contacting layers (comprising inorganic materials M1 or M3).

All examples except example 6 lead to highly crystalline layers.

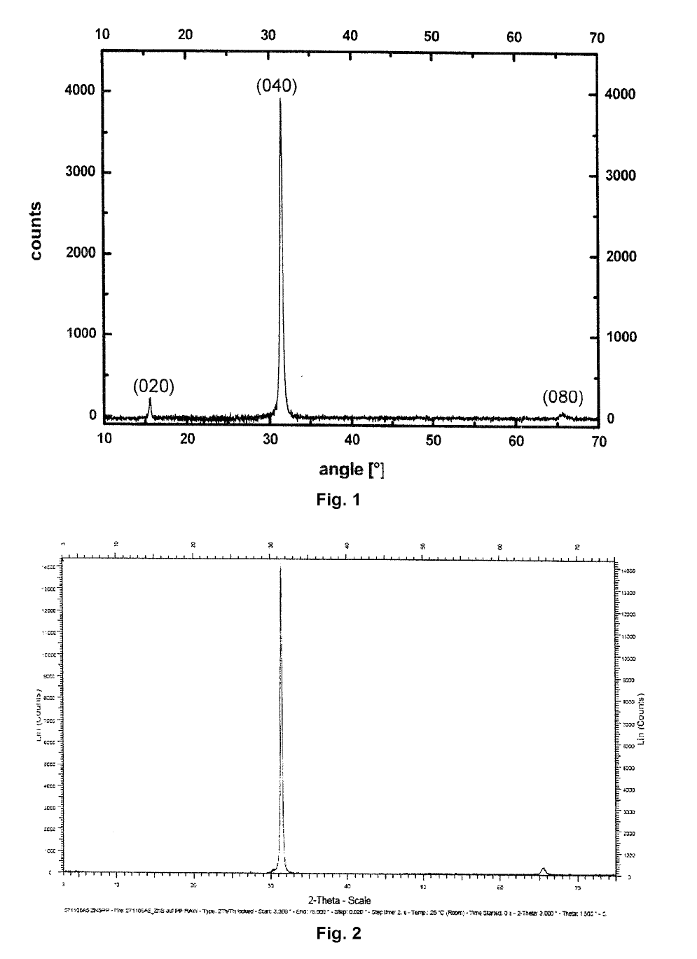

FIG. 1 shows XRD Data of a SnS crystalline thin film as deposited by a preferred embodiment of the invention on glass substrate (example 1). The significant peak (040) illustrates that the deposited SnS layer is highly crystalline and has a preferred orientation parallel to the substrate surface, which is indicated by the presence of just one (040)-peak.

FIG. 2 shows XRD Data of an SnS crystalline thin film as deposited by a preferred embodiment of the invention on PP substrate (example 2). Compared with FIG. 1 the data shown in FIG. 2 show an even higher crystalline layer.

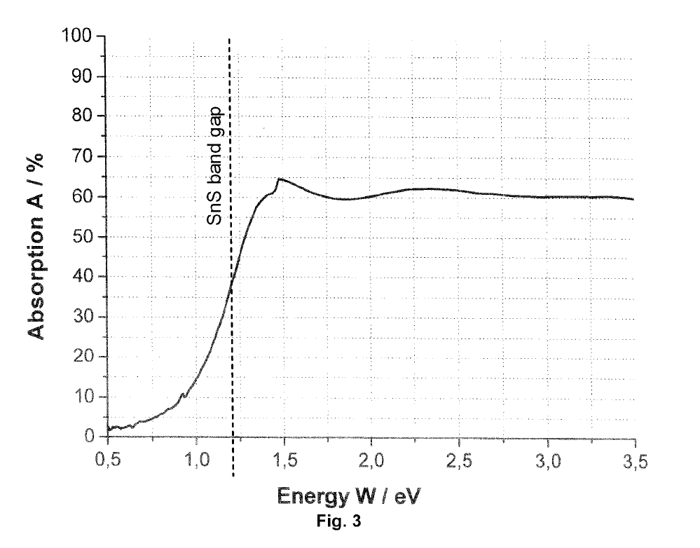

FIG. 3 shows absorption of SnS thin film deposited by a preferred embodiment of the invention (example 1). An SnS layer with a thickness of only 1 μm showed an absorption of over 60%. The absorption coefficient for energy above the band gap of SnS (1.2 eV) is above 10̂5/cm.

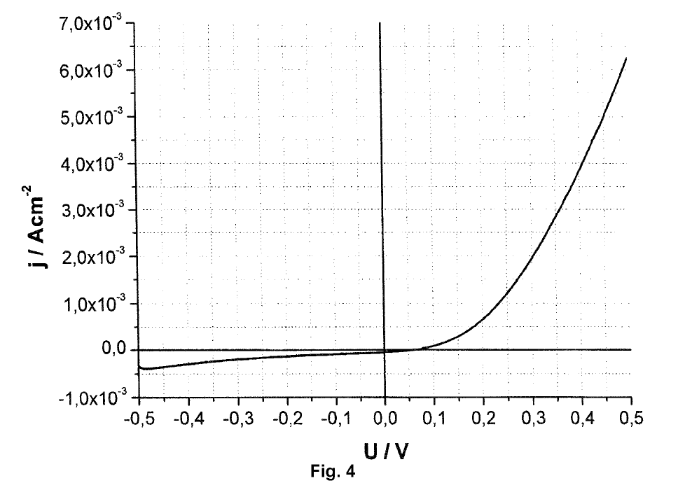

Diodes with SnS and with ZnO:Al as n-layer have been prepared. FIG. 4 shows a current voltage characteristic (I/V characteristic) of the so prepared diode, which is a typical characteristic for solar cells.

1. Method for depositing a film onto a substrate, with a sputter deposition process
wherein the sputter deposition process comprises direct current sputter deposition
wherein the film consists of at least 90 wt-% of an inorganic material M2 having semiconductor properties
whereby the film of the inorganic material M2 is directly deposited as crystalline structure, so that at least 50 wt-% of the deposited film has a crystalline structure
wherein the source material (target) used for the sputter deposition consists of at least 80 wt-% of the inorganic material M2
wherein the inorganic material M2 is selected from a group comprising binary, ternary, and quaternary salts comprising sulphur, selenium, and/or tellurium.

2. Method according to claim 1 wherein the inorganic material M2 is selected from the group of SnS, Sb2S3, Bi2S3, CdSe, In2S3, In2Se3, SnS, SnSe, PbS, PbSe, MoSe2, GeTe, Bi2Te3, or Sb2Te3; compounds of Cu, Sb, and S (or Se, Te) (e.g. CuSbS2, Cu2SnS3, CuSbSe2, Cu2SnSe3); compounds of Pb, Sb, and S (or Se, or Te) (PbSnS3, PbSnSe3) or a combination thereof.

3. Method according to claim 2 wherein the inorganic material M2 is SnS, Sb2S3, Bi2S3, SnSe, Sb2Se3, Bi2Se3, Sb2Te3, or a combination thereof.

4. Method according to claim 3 wherein the inorganic material M2 is selected from the group of SnS, Bi2S3 or a combination thereof.

5. Method according to claim 4 wherein the inorganic material M2 is SnS and the crystalline structure is orthorhombic.

6. Method according to claim 1 wherein at least during 90% of the depositing time the temperature T1 of the substrate is kept below 200° C.

7. Method according to claim 6 wherein the temperature T1 is kept below 100° C.

8. Method according to claim 6 wherein the temperature T1 is kept below 60° C.

9. Method according to claim 1 wherein the process parameters (t, T, p, P, U, . . . ) are set so that the film of the inorganic material M2 is deposited at a deposition rate of at least 60 nm/min (1 nm/s).

10. Method according to claim 1 wherein prior to the deposition of the film another layer of an inorganic material M1 has been deposited.

11. Method according to claim 10 wherein the inorganic material M1 is selected from the group of a metal or a conducting oxide.

12. Method according to claim 10 wherein the inorganic material M1 has been deposited by sputter deposition.

13. Method according to claim 1 wherein the substrate is selected from a group of ceramic, glass, polymer, plastic.

14. Product resulting from one of the methods according to claim 1.

15. Solar cell comprising a product resulting from one of the methods according to claim 1.

16. Solar cell comprising an absorber layer wherein the absorber layer is deposited by one of the methods according to claim 1.
